(19) United States
(12) Patent Application Publication
(10) Pub. No.: US 2024/0324232 A1
(43) Pub. Date: Sep. 26, 2024

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Minsu Jeong, Suwon-si (KR); Ahreum Kim, Suwon-si (KR); Pansuk Kwak, Suwon-si (KR)

(21) Appl. No.: 18/400,953

(22) Filed: Dec. 29, 2023

(30) Foreign Application Priority Data
Mar. 20, 2023 (KR) 10-2023-0035807

(51) Int. Cl. H10B 43/40; H01L 23/522; H10B 41/27; H10B 41/41; H10B 43/27

(52) U.S. Cl. CPC H10B 43/40; H01L 23/5223; H01L 28/86; H10B 41/27; H10B 41/41; H10B 43/27

(57) ABSTRACT

An example semiconductor device includes a first electrode structure, including a first connection portion and first finger portions extending from the first connection portion, and a second electrode structure, including a second connection portion and second finger portions extending from the second connection portion and alternately arranged with the first finger portions. The first electrode structure may include first lines and first contacts alternately stacked, the second electrode structure may include second lines and second contacts alternately stacked, and the first and second lines and the first and second contacts may be arranged at a first pitch on N levels among a plurality of levels, and are arranged at a second pitch greater than the first pitch on M levels of the plurality of levels, where N may be 3 or more, and M may be less than N.

### CROSS-REFERENCE TO RELATED APPLICATION

This application claims benefit of priority to Korean Patent Application No. 10-2023-0035807 filed on Mar. 20, 2023, in the Korean Intellectual Property Office, the disclosure of which is incorporated herein by reference in its entirety.

### BACKGROUND

The present disclosure relates to semiconductor devices and data storage systems including the same.

In a data storage system requiring data storage, a semiconductor device configured to store high-capacity data is required. Accordingly, a method for increasing a data storage capacity of a semiconductor device is being researched. Furthermore, a highly integrated semiconductor device is required. For example, as one method of increasing a degree of integration of a semiconductor device, a semiconductor device configured to vertically arrange memory cells and peripheral circuit regions is proposed.

### SUMMARY

An aspect of the present disclosure relates to a semiconductor device having an improved degree of integration.

Another aspect of the present disclosure relates to a data storage system including a semiconductor device having an improved degree of integration.

In some aspects of the present disclosure, a semiconductor device may include: a first semiconductor structure including a substrate, circuit elements on the substrate, and a capacitor structure on the circuit elements; and a second semiconductor structure including a plate layer on the first semiconductor structure, gate electrodes stacked to be spaced apart from each other in a first direction, perpendicular to an upper surface of the plate layer and sequentially stacked on the plate layer, and channel structures penetrating through the gate electrodes and extending in the first direction, wherein the capacitor structure may include: a first electrode structure including a first connection portion extending in a second direction, parallel to an upper surface of the substrate and first finger portions extending from the first connection portion in a third direction, perpendicular to the second direction; and a second electrode structure including a second connection portion extending in the second direction and second finger portions extending from the second connection portion in the third direction and alternately arranged with the first finger portions, wherein the first electrode structure may include first lines and first contacts alternately stacked on each other in the first direction, the second electrode structure may include second lines and second contacts alternately stacked on each other in the first direction, and in the second finger portions, a lower surface of at least one of the second contacts may be covered with an insulating layer so that the at least one of the second contacts is not connected to the second lines.

In some aspects of the present disclosure, a semiconductor device may include: a first electrode structure on a substrate and including a first connection portion extending in a first direction parallel to an upper surface of the substrate, and first finger portions extending from the first connection portion in a second direction, perpendicular to the first direction; a second electrode structure on the substrate and including a second connection portion extending in the first direction, and second finger portions extending from the second connection portion in the second direction and alternately arranged with the first finger portions; and an insulating layer between the first electrode structure and the second electrode structure, wherein the first electrode structure may include first lines and first contacts alternately stacked on each other in a third direction, perpendicular to an upper surface of the substrate, the second electrode structure may include second lines and second contacts alternately stacked on each other in the third direction, and the first and second lines and the first and second contacts may be arranged at a first pitch on N levels among a plurality of levels in the third direction, and are arranged at a second pitch greater than the first pitch on M levels of the plurality of levels, wherein N may be 3 or more, and M may be less than N.

In some aspects of the present disclosure, a data storage system may include: a semiconductor storage device including circuit elements on a substrate, memory cells, a capacitor structure, and an input/output pad; and a controller electrically connected to the semiconductor storage device through the input/output pad and configured to control the semiconductor storage device, wherein the capacitor structure includes: a first electrode structure including a first connection portion extending in a first direction parallel to an upper surface of the substrate, and first finger portions extending from the first connection portion in a second direction, perpendicular to the first direction; a second electrode structure including a second connection portion extending in the first direction, and second finger portions extending from the second connection portion in the second direction and alternately arranged with the first finger portions; and an insulating layer between the first electrode structure and the second electrode structure, wherein the first electrode structure includes first lines and first contacts alternately stacked on each other in a third direction, perpendicular to the upper surface of the substrate, the second electrode structure includes second lines and second contacts alternately stacked on each other in the third direction, and some of the second lines and the second contacts are vertically spaced apart from each other in the second finger portions.

The arrangement shape of lines and contacts may be optimized in the capacitor structure, thereby providing a semiconductor device having an improved degree of integration and a data storage system including the same.

Advantages and effects of the present application are not limited to the foregoing content and may be more easily understood in the process of describing a specific example implementation of the present disclosure.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a schematic block diagram of an example of a semiconductor device.

FIG. 2 is a circuit view illustrating an example of a charge pump circuit included in a voltage generator of a semiconductor device.

FIG. 3 is a schematic perspective view of an example of a semiconductor device.

FIGS. 4A to 4C are schematic plan views of an example of a capacitor structure of a semiconductor device.

FIGS. 5A and 5B are schematic cross-sectional views of an example of a capacitor structure of a semiconductor device.

FIGS. 6A and 6B are a plan view and a cross-sectional view of an example of a capacitor structure of a semiconductor device.

FIGS. 7A and 7B are a plan view and a cross-sectional view of an example of a capacitor structure of a semiconductor device.

FIGS. 8A to 8C are cross-sectional views of an example of a semiconductor device.

FIG. 9 is a view schematically illustrating an example of a data storage system including a semiconductor device.

### DETAILED DESCRIPTION

Hereinafter, example implementations of the present disclosure will be described with reference to the accompanying drawings.

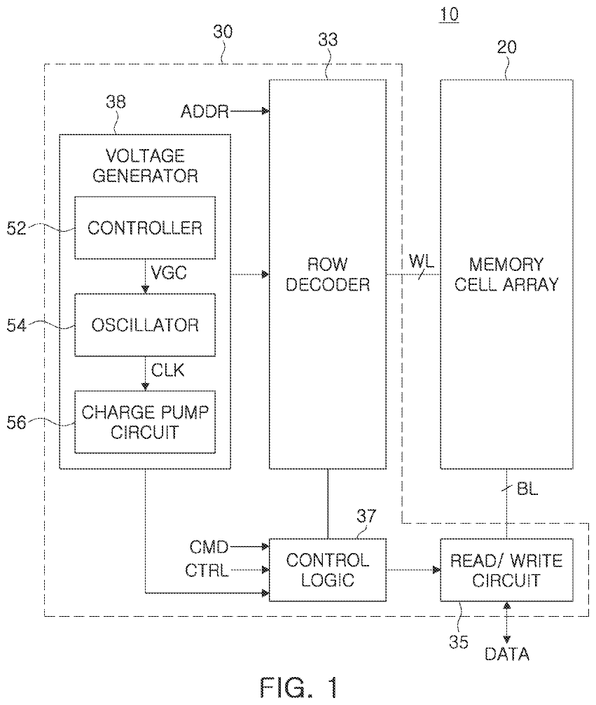

FIG. 1 is a schematic block diagram of an example of a semiconductor device.

Referring to FIG. 1, a semiconductor device 10 may include a memory cell array 20 and a peripheral circuit 30. The semiconductor device 10 may be a memory device, for example, a nonvolatile memory such as a flash memory, or a volatile memory such as a dynamic random access memory (DRAM) and a static random access memory (SRAM).

The memory cell array 20 may include a plurality of memory cells. The plurality of memory cells may be connected to a row decoder 33 through a plurality of word lines (WLs), and may be connected to a read/write circuit 35 through bit lines (BLs). In some example implementations, the plurality of memory cells arranged on the same row may be connected to the same WL, and the plurality of memory cells arranged in the same column may be connected to the same BL. In some example implementations, a plurality of memory blocks may be included, and each of the memory blocks may include a plurality of memory cells.

The peripheral circuit 30 may receive an address (ADDR), a command (CMD), and a control signal (CTRL) from the outside of the semiconductor device 10, and may transmit or receive data (DATA) to or from the outside of the semiconductor device 10. The peripheral circuit 30 may include the row decoder 33, the read/write circuit 35, a control logic 37, and a voltage generator 38 generating various voltages required for operation. In some implementations, the peripheral circuit 30 may further include various sub-circuits such as an input/output circuit and an error correction circuit for correcting an error in DATA read from the memory cell array 20.

The control logic 37 may be connected to the row decoder 33, the voltage generator 38, and the input/output circuit. The control logic 37 may control an overall operation of the semiconductor device 10. The control logic 37 may generate various internal control signals used in the semiconductor device 10 in response to the CTRL. For example, the control logic 37 may control a voltage level supplied to the WLs and the BLs when performing memory operations such as a program operation or an erase operation.

The row decoder 33 may select some of the plurality of memory cells in response to the ADDR, and may select at least one WL. The row decoder 33 may transmit voltage for performing a memory operation to the selected WL.

The read/write circuit 35 may be connected to the memory cell array 20 through BLs. The read/write circuit 35 may include a write driver or a sense amplifier. Specifically, during a program operation, the read/write circuit 35 may operate as a write driver and apply voltage according to the DATA to be stored in the memory cell array 20 to the BLs. Meanwhile, during a read operation, the read/write circuit 35 may operate as a sense amplifier to sense the DATA stored in the memory cell array 20.

The voltage generator 38 may include a controller 52, an oscillator 54, and a charge pump circuit 56.

The charge pump circuit 56 includes a plurality of charge pumps, and each of the plurality of charge pumps may include at least one switch element and at least one pumping capacitor. An output voltage of the charge pump circuit 56 may be used for an operation of the semiconductor device 10. For example, the row decoder 33 may input a bias voltage for performing a program operation, an erase operation and a read operation into the WL using the output voltage of the charge pump circuit 56.

The controller 52 may control an operation of the oscillator 54. For example, the controller 52 may determine a frequency of a clock signal (CLK) output by the oscillator 54 to the charge pump circuit 56 based on at least one of PVT (Process, Voltage, Temperature) information of the semiconductor device 10 and a target level of a voltage to be output by the charge pump circuit 56. For example, when the charge pump circuit 56 includes the plurality of charge pumps, the controller 52 may determine a selection charge pump that actually operates among the plurality of charge pumps.

The oscillator 54 may output a CLK turning on or off at least one switch element included in the charge pump circuit 56. The CLK output by the oscillator 54 may be determined in response to a control signal (VGC) from the controller 52. For example, the oscillator 54 may set a frequency and a swing range of the CLK differently depending on the VGC transmitted by the controller 52.

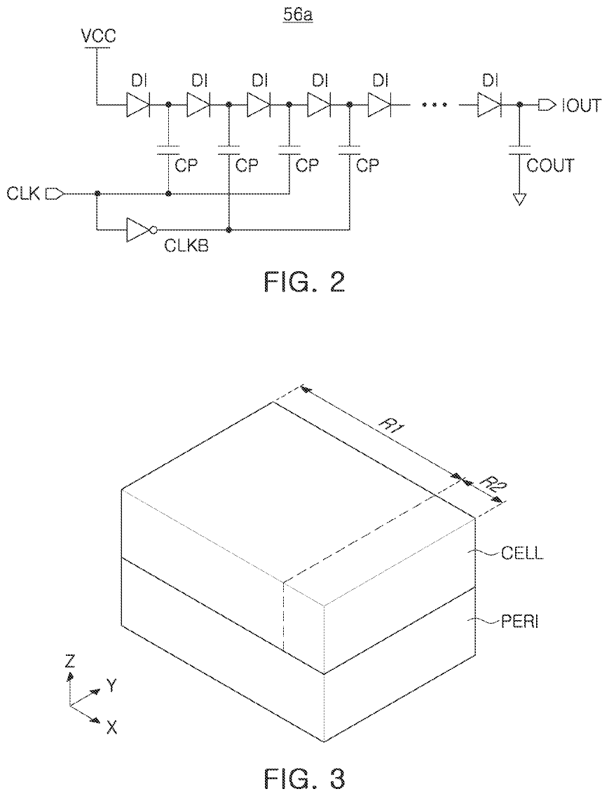

FIG. 2 is a circuit diagram illustrating an example of a charge pump circuit included in a voltage generator of a semiconductor device.

Referring to FIG. 2, a charge pump circuit 56a may include a plurality of diodes (DIs), a plurality of pumping capacitors (CPs), and an output capacitor (COUT). The plurality of DIs are connected in series with each other, and the plurality of CPs may be connected to a node between the plurality of DIs. A first diode may receive a power supply voltage (VCC) having a predetermined level, and a last diode may export an output current (IOUT) to an output node.

Each of the plurality of CPs may be charged or discharged by a CLK or a complementary clock signal (CLKB) phase-shifted to have a phase opposite to the CLK by an inverter (INV). For example, odd-numbered CPs may be charged or discharged by the CLK, and even-numbered CPs may be charged or discharged by the CLKB.

FIG. 3 is a schematic perspective view of an example of a semiconductor device.

Referring to FIG. 3, a semiconductor device may include a peripheral circuit structure (PERI) and a memory cell structure (CELL). The CELL may be disposed on the PERI. The CELL may be a region in which the memory cell array 20 of FIG. 1 is disposed, and the PERI may be a region in which the peripheral circuit 30 of FIG. 1 is disposed. In some implementations, contrary thereto, the CELL may be disposed below the PERI.

The CELL may include a first region R1 and a second region R2. The first region R1 may be a region in which a memory cell array is disposed. The second region R2 may correspond to a region for electrically connecting memory cells of the memory cell array to the peripheral circuit. The second region R2 may be disposed in least one end of the first region R1 in at least one direction, for example, in an X-direction.

The plurality of CPs constituting charge pump circuits 56 and 56a of FIGS. 1 and 2 may be disposed in the PERI. For example, the plurality of CPs may be disposed below the second region R2 of the CELL in the PERI, but the present disclosure is not limited thereto. In some implementations, the plurality of CPs may be disposed below the first region R1 of the CELL in the PERI.

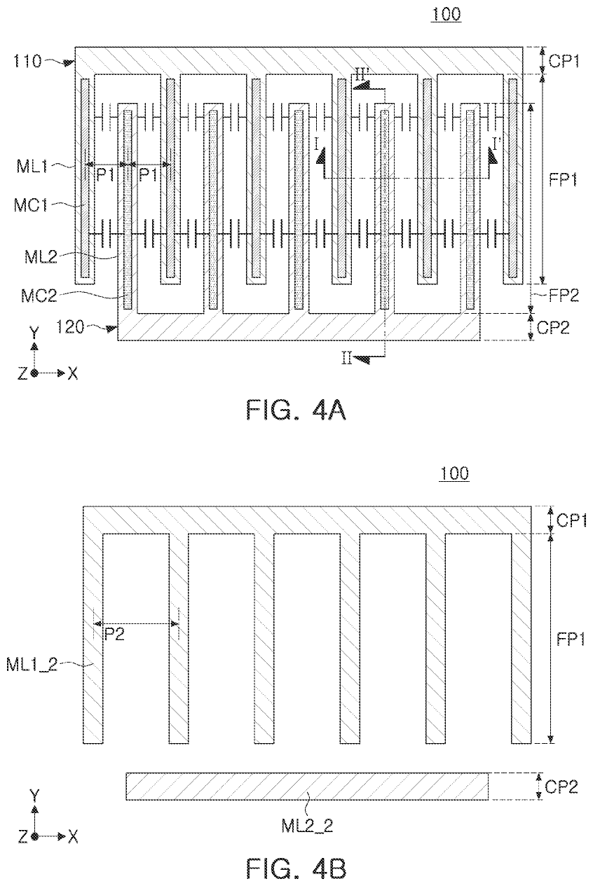

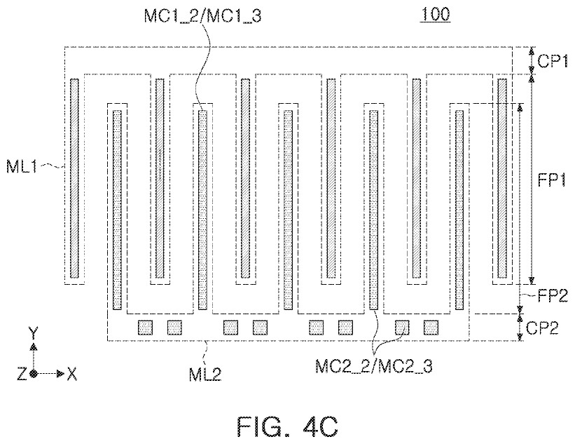

FIGS. 4A to 4C are schematic plan views of an example of a capacitor structure of a semiconductor device. FIGS. 4B and 4C illustrate plan views for some layers.

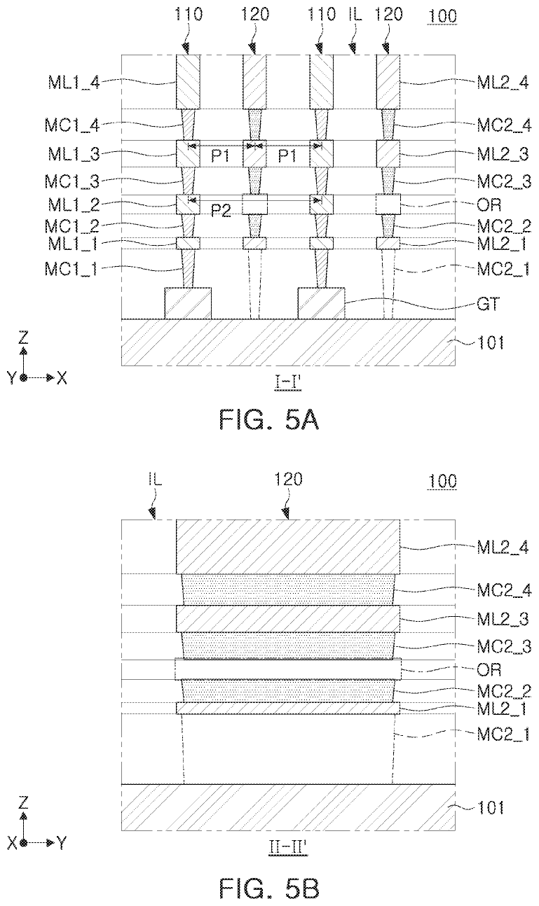

FIGS. 5A and 5B are schematic cross-sectional views of an example of a capacitor structure of a semiconductor device. FIGS. 5A and 5B respectively illustrate cross-sections taken along cut lines I-I′ and II-II′ of FIG. 4A.

Referring to FIGS. 4A to 5B, a capacitor structure 100 may include a first electrode structure 110, a second electrode structure 120, and a dielectric layer (IL). The capacitor structure 100 may form the CP of the charge pump circuits 56 and 56a described with reference to FIGS. 1 to 3.

The capacitor structure 100 may be disposed on a substrate 101. The first electrode structure 110 may be electrically connected to a gate structure (GT) on the substrate 101, and the second electrode structure 120 may be electrically connected to some regions of the substrate 101, for example, a well region or an impurity region, but the present disclosure is not limited thereto. The first electrode structure 110 and the second electrode structure 120 may have different potentials. In some implementations, the first electrode structure 110 and the second electrode structure 120 may receive an electrical signal through a separate interconnection connected to at least some of first and second lines ML1 and ML2.

The first electrode structure 110 may include a first connection portion CP1 extending in one direction, for example, in the X-direction, and first finger portions FP1 extending in one direction, for example, in a Y-direction from the first connection portion CP1. Similarly, the second electrode structure 120 may also include a second connection portion CP2 and second finger portions FP2 extending from the second connection portion CP2. The first connection portion CP1 and the second connection portion CP2 may be spaced apart from each other in the Y-direction, and the first finger portions FP1 and the second finger portions FP2 may be alternately disposed from each other in the X-direction.

The first electrode structure 110 may include first lines ML1 and first contacts MC1 stacked in a direction perpendicular to an upper surface of the substrate 101, for example, in the Z-direction. The second electrode structure 120 may include second lines ML2 and second contacts MC2 stacked in the Z-direction.

As illustrated in FIG. 5A, the first lines ML1 may include a first lower line ML1_1, a first intermediate line ML1_2, a first upper line ML1_3, and a first uppermost line ML1_4, which are sequentially stacked from the bottom, and the first contacts MC1 may include a first lower contact MC1_1, a first intermediate contact MC1_2, a first upper contact MC1_3, and a first uppermost contact MC1_4, which are sequentially stacked from the bottom. The second lines ML2 include a second lower line ML2_1, a second intermediate line ML2_2, a second upper line ML2_3, and a second uppermost line ML2_4, which are stacked sequentially from the bottom, and the second contacts MC2 may include a second lower contact MC2_1, a second intermediate contact MC2_2, a second upper contact MC2_3, and a second uppermost contact MC2_4, which are sequentially stacked from the bottom.

In some implementations, the number of layers of lines and contacts constituting each of the first and second lines ML1 and ML2 and the first and second contacts MC1 and MC2 may be variously changed. Furthermore, since the expressions “lower portion,” “intermediate portion,” “upper portion,” and “uppermost portion” in this specification are relative, they may be changed and referenced according to a referenced range. For example, when only the first intermediate line ML1_2, the first upper line ML1_3, and the first uppermost line ML1_4 of the first lines ML1 are described, they may be referred to as a first lower line, a first intermediate line, a first upper line, respectively.

The first and second electrode structures 110 and 120 may include an electrode absence region (OR). The OR may be a region in which at least one line or contact is omitted exceptionally in a regular arrangement of the entire capacitor structure 100. In this example, the second intermediate line ML2_2 may not be disposed on the second finger portions FP2. Accordingly, the OR may be formed on a level of the second intermediate line ML2_2. The OR may be filled with the IL.

The first lines ML1 may extend in a line shape, and as illustrated in FIG. 4A, the first lines ML1 may form the first connection portion CP1 and first finger portions FP1. The second lines ML2 may extend in a line shape, and except for the second intermediate line ML2_2, the second lines ML2 may form the second connection portion CP2 and the second finger portions FP2, as illustrated in FIG. 4A. As illustrated in FIG. 4B, the second intermediate line ML2_2 may be disposed only in the second connection portion CP2, and may not form the second finger portions FP2.

As illustrated in FIG. 4A, the first contacts MC1 may be disposed in the first finger portions FP1. The second contacts MC2 may be disposed in the second finger portions FP2, as illustrated in FIG. 4A. The first and second contacts MC1 and MC2 may have a line shape extending in the Y-direction along the first and second finger portions FP1 and FP2, respectively. Accordingly, each of the first and second finger portions FP1 and FP2 may have a wall shape as illustrated in FIG. 5B. In the first and second finger portions FP1 and FP2, the first and second contacts MC1 and MC2 may have a length shorter than those of the first and second lines ML1 and ML2 in the Y-direction, but the present disclosure is not limited thereto.

The second intermediate contacts MC2_2 and the second upper contacts MC2_3 among the second contacts MC2 may be further disposed in the second connection portion CP2, as illustrated in FIG. 4C. In the second connection portion CP2, a plurality of second intermediate contacts MC2_2 and a plurality of second upper contacts MC2_3 may be disposed in the X-direction such that they are connected to the second intermediate line ML2_2. However, a shape in which the second intermediate contacts MC2_2 and the second upper contacts MC2_3 are disposed in the second connection portion CP2 is not limited thereto. In some implementations, the second intermediate contacts MC2_2 and the second upper contact MC2_3 have a line shape extending from the second connection portion CP2 in the X-direction. In some implementations, the first lower contacts MC1_1 and the second lower contacts MC2_1 disposed at a lowermost portion are further disposed respectively in the first connection portion CP1 and the second connection portion CP2, or are disposed respectively only in the first connection portion CP1 and the second connection portion CP2.

In one first finger portion FP1, the first lines ML1 and the first contacts MC1 may be disposed such that central axes thereof in the X-direction coincide with each other. In one second finger portion FP2, the second lines ML2 and the second contacts MC2 may be disposed such that central axes thereof in the X-direction coincide with each other. However, since the second intermediate line ML2_2 is not disposed in the second finger portion FP2, as illustrated in FIGS. 5A and 5B, a region corresponding to a level of the second intermediate line ML2_2 may be an OR in which a conductive material is not disposed. The second intermediate contact MC2_2 below the second intermediate line ML2_2 and the second upper contact MC2_3 on the second intermediate line ML2_2 may be spaced apart from each other in the Z-direction with the OR interposed therebetween. An upper surface of the second intermediate contact MC2_2 and a lower surface of the second upper contact MC2_3 may be covered with the IL.

Between the first and second finger portions FP1 and FP2 disposed adjacent to each other in the X-direction, the first and second lines ML1 and ML2 may be disposed at a first pitch P1 except for the second intermediate line ML2_2. Here, the pitch may denote a distance between the center and the center or a distance from one end to one end. The first and second contacts MC1 and MC2 may also be disposed at the first pitch P1. The first pitch P1 may range from, for example, about 140 nm to about 240 nm. Since the second intermediate line ML2_2 is not disposed in the second finger portions FP2, lines at a level corresponding to the second intermediate line ML2_2, that is, first intermediate lines ML1_2 may be disposed at a second pitch P2 in the X-direction. The second pitch P2 may be greater than the first pitch P1. For example, the second pitch P2 may be twice the first pitch P1, but the present disclosure is not limited thereto.

In the capacitor structure 100 of this example, at least one of the first and second lines ML1 and ML2 constituting the first and second finger portions FP1 and FP2 is omitted. In some implementations, the second intermediate line ML2_2 is omitted, and accordingly, even if it is difficult to unify a pitch of a certain level of lines with another level of lines due to process or design reasons, a structure of the capacitor may be easily fabricated. For example, on the levels of the first intermediate line ML1_2 and the second intermediate line ML2_2, the pitches of the lines may be arranged at a third pitch greater than the first pitch P1 as a minimum pitch. In this case, an area of the capacitor structure increases in a comparative example of changing all the first and second lines ML1 and ML2 and the first and second contacts MC1 and MC2 to be arranged in the third pitch. However, according to this example, the second intermediate line ML2_2 disposed in the second finger portion FP2 may be removed to secure capacitance while minimizing an area of the capacitor structure 100.

The first electrode structure 110 and the second electrode structure 120 may include a metal material, for example, tungsten (W), copper (Cu), or aluminum (Al). The IL may be an insulating layer including an insulating material. For example, the IL may include silicon oxide, silicon nitride, silicon carbide, or silicon oxynitride.

As illustrated in FIG. 4A, the first line ML1, the second line ML2, and the IL disposed therebetween, which are disposed on the same level in the first and second finger portions FP1 and FP2 may form one metal-insulator-metal (MIM) capacitor, and the first contact MC1, the second contact MC2, and the IL disposed therebetween, which are disposed on the same level, may form one MIM capacitor. Since the first contacts MC1 and the second contacts MC2 are arranged in a line shape in the first and second finger portions FP1 and FP2, the capacitance of the capacitor structure 100 may be maximized. In some implementations, the first lower contacts MC1_1 and the second lower contacts MC2_1 on a lowest level may not form a capacitor. In this case, arrangement forms of the first lower contacts MC1_1 and the second lower contacts MC2_1 may be different from those of the other first contacts MC1 and second contacts MC2.

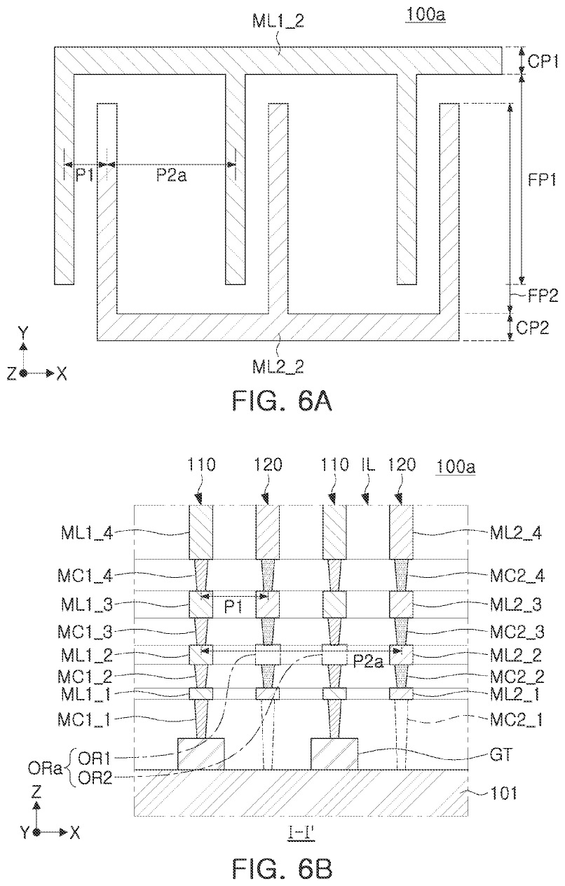

FIGS. 6A and 6B are a plan view and a cross-sectional view of an example of a capacitor structure of a semiconductor device. FIG. 6A illustrates a plan view of some layers, and FIG. 6B illustrates a cross section corresponding to FIG. 5A.

Referring to FIGS. 6A and 6B, in a capacitor structure 100a, an arrangement of an electrode absence region ORa may be different from the example implementations of FIGS. 4A to 5B. Specifically, the first intermediate line ML1_2 and the second intermediate line ML2_2 may not be disposed in some first finger portions FP1 and some second finger portions FP2. As illustrated in FIG. 6A, one first intermediate line ML1_2 may be disposed for every two first finger portions FP1, and one second intermediate line ML2_2 may be disposed for every two second finger portions FP2. Accordingly, as illustrated in FIG. 6B, the electrode absence region ORa may include a first electrode absence region OR1 corresponding to the first intermediate line ML1_2 and a second electrode absence region OR2 corresponding to the second intermediate line ML2_2.

Between the first and second finger portions FP1 and FP2 disposed adjacent to each other in the X-direction, the first and second lines ML1 and ML2 may be disposed at the first pitch P1 except for the first intermediate line ML1_2 and the second intermediate line ML2_2. The first and second contacts MC1 and MC2 may also be disposed at the first pitch P1. On a level corresponding to the first intermediate line ML1_2 and the second intermediate line ML2_2, the first intermediate line ML1_2 and the second intermediate line ML2_2 may be disposed at the first pitch P1 and a second pitch P2a in the X-direction. The second pitch P2a may be greater than the first pitch P1. For example, the second pitch P2a may be three times the first pitch P1, but the present disclosure is not limited thereto.

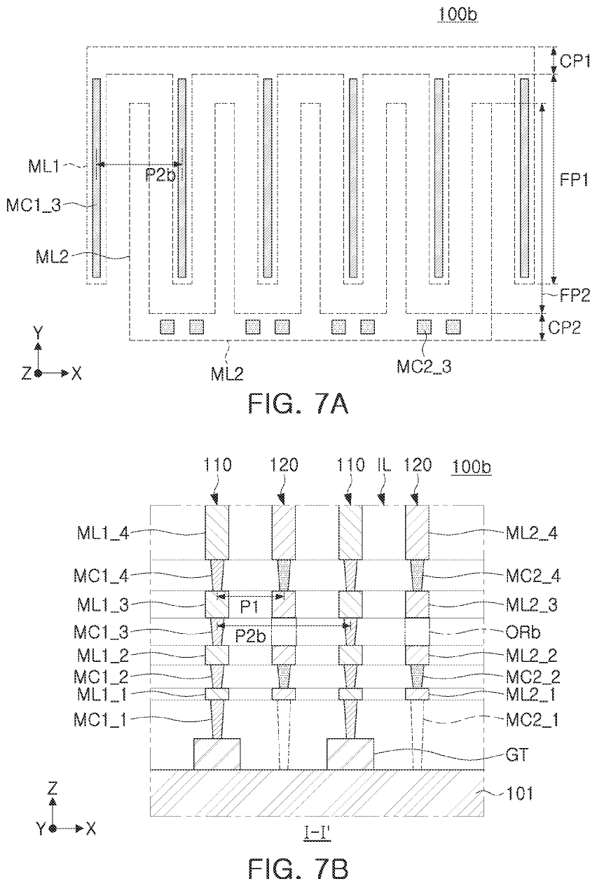

FIGS. 7A and 7B are a plan view and a cross-sectional view of an example of a capacitor structure of a semiconductor device. FIG. 7A illustrates a plan view of some layers, and FIG. 7B illustrates a cross section corresponding to FIG. 5A.

Referring to FIGS. 7A and 7B, in a capacitor structure 100b, an arrangement of an electrode absence region ORb may be different from the example implementations of FIGS. 4A to 6B. Specifically, the second upper contact MC2_3 may not be disposed in the second finger portions FP2. As illustrated in FIG. 7A, the second upper contact MC2_3 may be disposed only in the second connection portion CP2. Accordingly, as illustrated in FIG. 7B, the electrode absence region ORb may be disposed in a region corresponding to the second upper contact MC2_3. The second intermediate line ML2_2 and the second upper line ML2_3 disposed above and below the electrode absence region ORb may not be vertically connected to each other. An entire upper surface of the second intermediate line ML2_2 and an entire lower surface of the second upper line ML2_3 may be covered with an IL.

Between the first and second finger portions FP1 and FP2 disposed adjacent to each other in the X-direction, the first and second lines ML1 and ML2 may be disposed at the first pitch P1. The first and second contacts MC1 and MC2 may also be disposed at the first pitch P1 except for the first upper contact MC1_3 and the second upper contact MC2_3. On a level corresponding to the first upper contact MC1_3 and the second upper contact MC2_3, the first upper contact MC1_3 may be disposed at a second pitch P2b greater than the first pitch P1 in the X-direction. For example, the second pitch P2b may be twice the first pitch P1, but the present disclosure is not limited thereto.

As illustrated in the example implementations of FIGS. 5A and 5B, the electrode absence region ORa may be disposed in both the first and second electrode structures 110 and 120, and as illustrated in the example implementations of FIGS. 6A and 6B, the electrode absence region ORb may be disposed in a region corresponding to the contacts MC1 and MC2. As described above, in some example implementations, positions of the electrode absence regions OR, ORa and ORb may be variously changed in the first and second lines ML1 and ML2 and the first and second contacts MC1 and MC2. Furthermore, in some example implementations, the electrode absence region may be disposed in a region corresponding to lines and/or contacts disposed not only on one level but also on a plurality of different levels.

In some example implementations, the first and second lines ML1 and ML2 and the first and second contacts MC1 and MC2 may be disposed at the first pitch P1 on N levels of a plurality of levels in the Z-direction, and may be disposed at a second pitch P2 greater than the first pitch P1 on M levels of the plurality of levels, and N may be 3 or more, and M may be less than N.

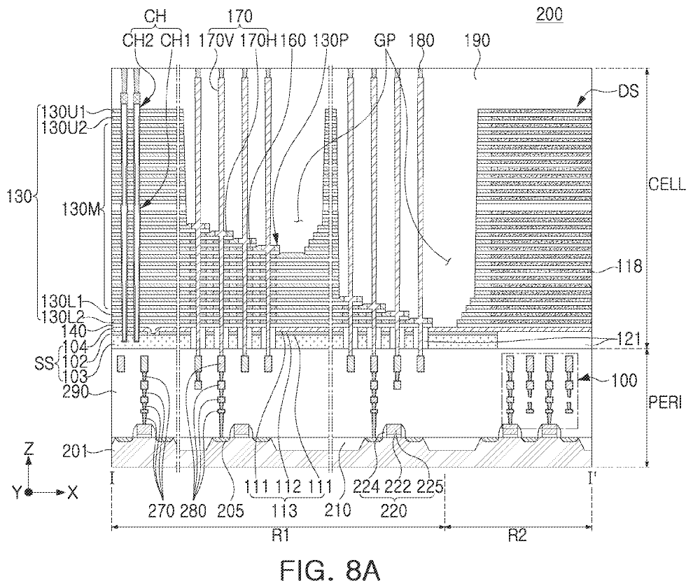

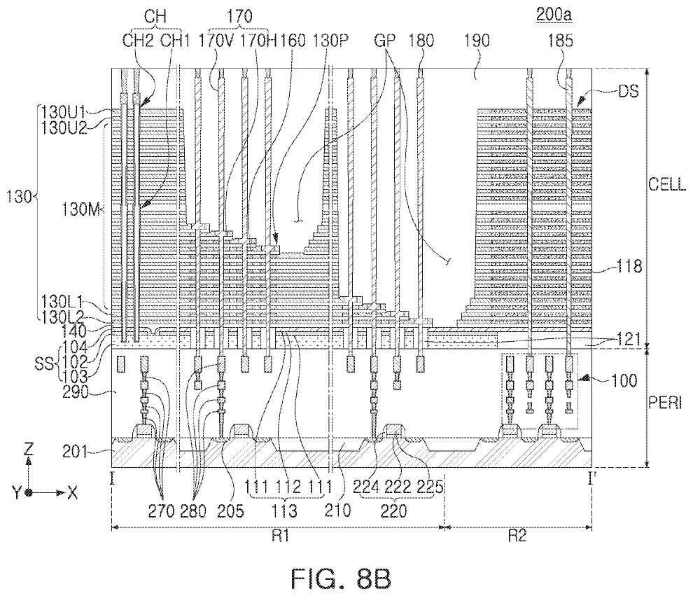

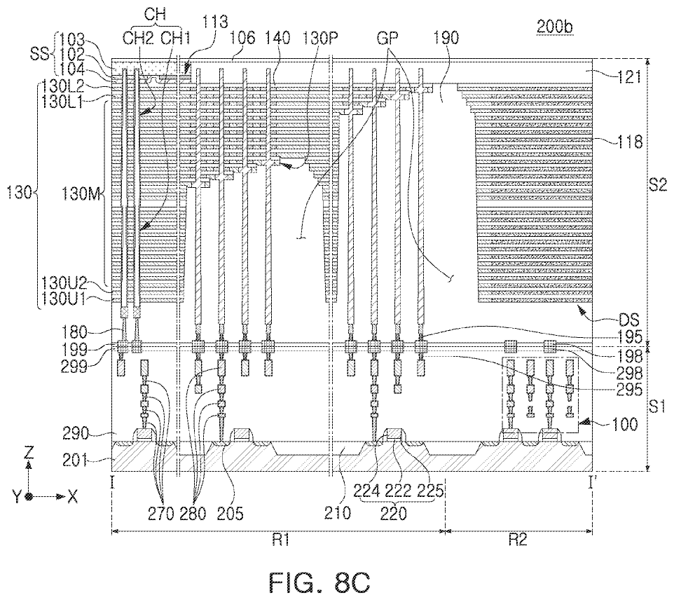

FIGS. 8A to 8C are cross-sectional views of an example of a semiconductor device.

Referring to FIG. 8A, a semiconductor device 200 may include a PERI as a first semiconductor structure including a substrate 201, and a CELL as a second semiconductor structure including a plate layer 103.

The PERI may include the substrate 201, impurity regions 205 and element isolation layers 210 in the substrate 201, circuit elements 220 disposed on substrate 201, a peripheral region insulating layer 290, circuit contact plugs 270, and circuit interconnection lines 280.

The substrate 201 may have an upper surface extending in the X-direction and the Y-direction. An active region may be defined in the substrate 201 by the element isolation layers 210. The impurity regions 205 including impurities may be disposed in a portion of the active region. The substrate 201 may include a semiconductor material, for example, a Group IV semiconductor, a Group III-V compound semiconductor, or a Group II-VI compound semiconductor. The substrate 201 may be provided as a bulk wafer or an epitaxial layer.

The circuit elements 220 may include a planar transistor. Each of the circuit elements 220 may include a circuit gate dielectric layer 222, a spacer layer 224, and a circuit gate electrode 225. The impurity regions 205 may be disposed as source/drain regions in the substrate 201 at both sides of the circuit gate electrode 225. In the implementations illustrated herein, the phrase source/drain region may be understood to mean a source terminal region or a drain terminal region of a transistor.

The peripheral region insulating layer 290 may be disposed on the circuit element 220 on the substrate 201. The peripheral region insulating layer 290 may include a plurality of insulating layers formed in different process operations. The peripheral region insulating layer 290 may be formed of an insulating material.

The circuit contact plugs 270 and the circuit interconnection lines 280 may form a circuit interconnection structure electrically connected to the circuit elements 220 and the impurity regions 205. The circuit contact plugs 270 may have a cylindrical shape, and the circuit interconnection lines 280 may have a line shape. An electrical signal may be applied to the circuit element 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, and may have a line shape, and may be arranged in a form of a plurality of layers. The circuit contact plugs 270 and the circuit interconnection lines 280 may include conductive materials, such as tungsten (W), copper (Cu), and aluminum (Al), and each configuration may further include a diffusion barrier. In some implementations, the number of layers of the circuit contact plugs 270 and the circuit interconnection lines 280 are different than the number shown herein.

The circuit interconnection structure may include a capacitor structure 100. The capacitor structure 100 may include lines and contacts disposed on the same level as each of the other circuit contact plugs 270 and circuit interconnection lines 280. The capacitor structure 100 may be disposed to be horizontally spaced apart from other regions of the circuit interconnection structure. The capacitor structure 100 may be electrically connected to some of the circuit elements 220. The capacitor structure 100 may be disposed below the second region R2, but the present disclosure is not limited thereto. In some example implementations, the capacitor structure 100 may be disposed below the first region R1 of the CELL, or may be disposed below both the first and second regions R1 and R2. The descriptions with reference to FIGS. 4A to 5B may be identically applied to other descriptions of the capacitor structure 100. In the capacitor structure 100, when the second intermediate lines ML2_2 are omitted and the first intermediate lines ML1_2 are disposed at the second pitch P2, the circuit interconnection lines 280 may be disposed at a pitch greater than or equal to the second pitch P2 on a level corresponding to the first intermediate lines ML1_2 and the second intermediate lines ML2_2 in other regions of the circuit interconnection structure. In some example implementations, the capacitor structure 100 may have the structure of the example implementations of FIGS. 6A to 7B.

The CELL has first and second regions R1 and R2, and may include a source structure (SS), gate electrodes 130 stacked on the SS, interlayer insulating layers 140 alternately stacked with the gate electrodes 130, channel structures (CHs) disposed to penetrate through a stack structure of the gate electrodes 130, and contact plugs 170 connected to the gate electrodes 130 and extending vertically. The CELL may further include a horizontal insulating layer 113 disposed below the gate electrodes 130, substrate insulating layers 121 disposed to penetrate through the plate layer 103, studs 180 on the contact plugs 170, and a cell region insulating layer 190 covering the gate electrodes 130.

In the CELL, the first region R1 may be a region in which the gate electrodes 130 are stacked vertically to form memory cells or connected to the contact plugs 170. The second region R2 may be a region in which a dummy structure (DS) including sacrificial insulating layers 118 is disposed.

The SS may include the plate layer 103, a first horizontal conductive layer 102, and a second horizontal conductive layer 104, which are sequentially stacked. The plate layer 103 has a plate shape and may function as at least a portion of a common source line of the semiconductor device 200. The plate layer 103 may include a conductive material, for example, a semiconductor material. The plate layer 103 may further include impurities. The plate layer 103 may be provided as a polycrystalline semiconductor layer such as a polycrystalline silicon layer or an epitaxial layer.

The first and second horizontal conductive layers 102 and 104 may be sequentially stacked and disposed on an upper surface of the plate layer 103 in a region in which the CHs are disposed. The first horizontal conductive layer 102 may function as a portion of a common source line of the semiconductor device 200, and, for example, function as a common source line along with the plate layer 103. The first horizontal conductive layer 102 may be directly connected to a channel layer in the CH. The first and second horizontal conductive layers 102 and 104 may include a semiconductor material, for example, polycrystalline silicon.

The horizontal insulating layer 113 may be disposed on the plate layer 103 on the same level as the first horizontal conductive layer 102. The horizontal insulating layer 113 may include first and second horizontal insulating layers 111 and 112 alternately stacked on the plate layer 103. The horizontal insulating layer 113 may be layers that remain after a portion thereof is replaced with the first horizontal conductive layer 102 in a manufacturing process of the semiconductor device 200. The horizontal insulating layer 113 may include silicon oxide, silicon nitride, silicon carbide, or silicon oxynitride. The first horizontal insulating layers 111 and the second horizontal insulating layer 112 may include different insulating materials

The substrate insulating layers 121 may be disposed to penetrate through the plate layer 103, the horizontal insulating layer 113, and the second horizontal conductive layer 104. The substrate insulating layer 121 may include an insulating material, for example, silicon oxide, silicon nitride, silicon carbide, or silicon oxynitride.

The gate electrodes 130 may be vertically spaced apart from each other and stacked on the plate layer 103 to form a stack structure along with the interlayer insulating layers 140. The stack structure may include lower and upper stack structures as stacked vertically. The gate electrodes 130 may include first upper gate electrodes 130U1 and 130U2 constituting string selection transistors, memory gate electrodes 130M constituting the plurality of memory cells, and second lower gate electrodes 130L1 and 130L2 constituting a ground selection transistor. The number of memory gate electrodes 130M constituting the memory cells may be determined according to the capacity of the semiconductor device 200.

The gate electrodes 130 may be vertically spaced apart from each other on the first region R1, and may extend by different lengths in the X-direction to form stair-shaped step structures in the gate pad regions (GPS). The gate electrodes 130 may have a shape removed from an upper portion thereof by a predetermined depth in the GPs, and the GPs may have different depths. The GPs may have a shape in which a depth thereof increases as the GPs move away from the CHs in the X-direction.

The gate electrodes 130 may form first and second step structures in an asymmetrical form in the X-direction in each of the GPs. The first step structure may be a step structure which is relatively disposed adjacent to the CHs and in which a level thereof is lowered in the X-direction, and the second step structure may be a step structure which is relatively far from the CHs and in which a level thereof is increased in the X-direction. For example, in each of the GPs, an inclination of the first step structure may be less than an inclination of the second step structure. However, in some example implementations, the first and second step structures may have symmetrical shapes. In the first step structure, the gate electrodes 130 may be connected to the contact plugs 170 and in the second step structure, the gate electrodes 130 may form a dummy region or a dummy structure that is not connected to the contact plugs 170.

The heights of uppermost surfaces of the dummy structures of the GPs may be identical to each other, but the present disclosure is not limited thereto. In some example implementations, the heights of the uppermost surfaces of the dummy structures may be lowered while moving away from the CHs in the X-direction. In some implementations, a specific shape of the step structure and the number of gate electrodes 130 forming each step structure are not limited to those illustrated in FIG. 8A. In some implementations, the gate electrodes 130 are disposed to have a step structure with each other in the Y-direction.

Due to the first step structure, the gate electrodes 130 may have contact regions 130P exposed upward from the interlayer insulating layers 140 by allowing a lower gate electrode 130 to extend longer than an upper gate electrode 130. The gate electrodes 130 may be connected to the contact plugs 170 in the contact regions 130P, which are end regions, respectively.

The gate electrodes 130 may include a metal material, for example, tungsten W. According to an example implementation, the gate electrodes 130 include a polycrystalline silicon material or a metal silicide material. All of the gate electrodes 130 may include the same material. In some example implementations, the gate electrodes 130 may further include a diffusion barrier, and, for example, the diffusion barrier may include tungsten nitride (WN), tantalum nitride (TaN), titanium nitride (TiN), or combinations thereof.

The interlayer insulating layers 140 may be disposed between the gate electrodes 130. Similarly to the gate electrodes 130, the interlayer insulating layers 140 may also be spaced apart from each other in a direction perpendicular to the upper surface of the plate layer 103 and extend in the X-direction. The interlayer insulating layers 140 may include an insulating material such as silicon oxide or silicon nitride.

The sacrificial insulating layers 118 may be alternately stacked with the interlayer insulating layers 140 outside the gate electrodes 130 to form a DS. The sacrificial insulating layers 118 may be disposed on the plate layer 103 and the substrate insulating layer 121. The sacrificial insulating layers 118 may be disposed on the same height level as the gate electrodes 130 with the same thickness, and may be disposed to come into contact with side surfaces of the gate electrodes 130. The sacrificial insulating layers 118 may be alternately stacked with the interlayer insulating layers 140 to form, for example, a through insulating region having a through-via disposed therein. The sacrificial insulating layers 118 may be disposed to have a width equal to or different from that of the lower substrate insulating layer 121. The sacrificial insulating layers 118 may be formed of an insulating material different from that of the interlayer insulating layers 140, and may include, for example, silicon oxide, silicon nitride, or silicon oxynitride.

The CHs may penetrate through the gate electrodes 130 and extend in the Z-direction, and may be connected to the plate layer 103. Each of the CHs may form one memory cell string, and may be spaced apart from each other while forming rows and columns on the plate layer 103. The CHs may be disposed to form a lattice pattern on an X-Y plane or may be disposed in a zigzag form in one direction. The CHs have a columnar shape and may have inclined side surfaces that become narrower as the CHs are closer to the plate layer 103.

The CHs may include lower and upper channel structures CH1 and CH2 stacked vertically. The CHs may have a shape in which the lower channel structures CH1 and the upper channel structures CH2 are connected to each other, and may have a bent portion due to a difference in width in a connection region. However, in some example implementations, the number of channel structures stacked in the Z-direction may be variously changed. Each of the CHs may include a channel layer, a gate dielectric layer, a channel buried insulating layer, and an upper channel pad disposed in a channel hole.

The contact plugs 170 may be connected to the contact regions 130P of the gate electrodes 130. The contact plugs 170 may penetrate through at least a portion of the cell region insulating layer 190 and may be connected to each of the contact regions 130P of the gate electrodes 130 exposed upward. The contact plugs 170 may penetrate through the gate electrodes 130 below the contact regions 130P and penetrate through the second horizontal conductive layer 104, the horizontal insulating layer 113, and the plate layer 103, and may be connected to circuit interconnection lines 280 in the PERI. The contact plugs 170 may be spaced apart from the gate electrodes 130 below the contact regions 130P by the contact insulating layers 160. The contact plugs 170 may be spaced apart from the plate layer 103, the horizontal insulating layer 113, and the second horizontal conductive layer 104 by the substrate insulating layers 121.

Each of the contact plugs 170 may have a shape expanded horizontally from the contact region 130P. The contact plug 170 may include a vertical extension portion 170V extending in the Z-direction and a horizontal extension portion 170H extending horizontally from the vertical extension portion 170V to come into contact with the gate electrode 130. The horizontal extension portion 170H may be disposed along a circumference of the vertical extension portion 170V, and may be surrounded by the gate electrode 130. The contact plugs 170 may be spaced apart from the gate electrodes 130 below the contact regions 130P, that is, gate electrodes 130 not electrically connected, by the contact insulating layers 160.

The contact plugs 170 may include a conductive material, such as at least one of tungsten (W), copper (Cu), aluminum (Al), and alloys thereof. In some example implementations, the contact plugs 170 may include a barrier layer extending along a side surface and bottom surface thereof, or may have an air gap therein.

The contact insulating layers 160 may be disposed below the contact regions 130P to surround side surfaces of each of the contact plugs 170. The contact insulating layers 160 may be spaced apart from each other in the Z-direction around each of the contact plugs 170. The contact insulating layers 160 may be disposed on substantially the same level as the gate electrodes 130, respectively. The contact insulating layers 160 may include insulating materials, such as silicon oxide, silicon nitride, or silicon oxynitride.

The studs 180 may form a cell interconnection structure electrically connected to the memory cells in the CELL. The studs 180 may be connected to the CHs and the contact plugs 170, and may be electrically connected to the CHs and the gate electrodes 130. The studs 180 may include metal, for example, tungsten (W), copper (Cu), and aluminum (Al).

The cell region insulating layer 190 may be disposed to cover the stack structure of the gate electrodes 130 and the contact plugs 170. The cell region insulating layer 190 may be formed of an insulating material, or may be formed of a plurality of insulating layers.

Referring to FIG. 8B, in the semiconductor device 200a, the CELL may further include a through-via 185.

The through-via 185 may penetrate through the DS and be connected to the capacitor structure 100 of the PERI. The through-via 185 may include a conductive material, for example, tungsten (W), copper (Cu), and aluminum (Al).

Referring to FIG. 8C, a semiconductor device 200b may include a first semiconductor structure S1 and a second semiconductor structure S2 bonded by a wafer bonding method.

A description of the PERI of FIG. 8A may be applied to the first semiconductor structure S1. However, the first semiconductor structure S1 may further include bonding structures such as first bonding vias 295, first bonding metal layers 298, and first bonding insulating layer 299. The first bonding vias 295 may be disposed in an upper portion of an uppermost circuit interconnection lines 280 and connected to the circuit interconnection lines 280. At least a portion of the first bonding metal layers 298 may be connected to the first bonding vias 295 on the first bonding vias 295. The first bonding metal layers 298 may be connected to second bonding metal layers 198 of the second semiconductor structure S2. The bonding metal layers 298 may provide an electrical connection path according to a bonding of the first semiconductor structure S1 and the second semiconductor structure S2 along with the second bonding metal layers 198. Some of the first bonding metal layers 298 may not be connected to lower circuit interconnection lines 280 but may be disposed only for bonding. The first bonding vias 295 and the first bonding metal layers 298 may include a conductive material, for example, copper (Cu). The first bonding insulating layer 299 may be disposed around the first bonding metal layers 298. The first bonding insulating layer 299 may also function as a diffusion barrier of the first bonding metal layers 298, and may include, for example, at least one of SiN, SiON, SiCN, SiOC, SiOCN, and SiO.

A description of the CELL of FIG. 8A may be applied to the second semiconductor structure S2. The second semiconductor structure S2 may further include bonding structures such as second bonding vias 195, second bonding metal layers 198, and second bonding insulating layers 199. The second semiconductor structure S2 may further include a passivation layer 106 covering the upper surface of the plate layer 103.

The second bonding vias 195 and the second bonding metal layers 198 may be disposed below the cell interconnection structure, for example, the studs 180. In some example implementations, interconnection lines may be further disposed between the second bonding vias 195 and the studs 180. The second bonding vias 195 may connect the studs 180 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material, for example, copper (Cu). The second bonding insulating layer 199 may include, for example, at least one of SiO, SiN, SiCN, SiOC, SiON, and SiOCN.

The first and second semiconductor structures S1 and S2 may be bonded by a bonding of the first bonding metal layers 298 and the second bonding metal layers 198 and a bonding of the first bonding insulating layer 299 and the second bonding insulating layer 199. The bonding of the first bonding metal layers 298 and the second bonding metal layers 198 may be, for example, a copper (Cu)-to-copper (Cu) bonding, and the bonding of the first bonding insulating layer 299 and the second bonding insulating layer 199 may be, for example, a dielectric-dielectric bonding such as a SiCN-to-SiCN bonding. The first and second semiconductor structures S1 and S2 may be bonded by a hybrid bonding including the copper (Cu)-to-copper (Cu) bonding and the dielectric-to-dielectric bonding.

The passivation layer 106 may be disposed on the upper surface of the plate layer 103 and may protect the semiconductor device 200b. The passivation layer 106 and the upper insulating layer 161 may include an insulating material, for example, at least one of silicon oxide, silicon nitride, and silicon carbide, and may be formed of a plurality of insulating layers in some example implementations. In this example, upper ends of the contact plugs 170 may be disposed in the substrate insulating layer 121.

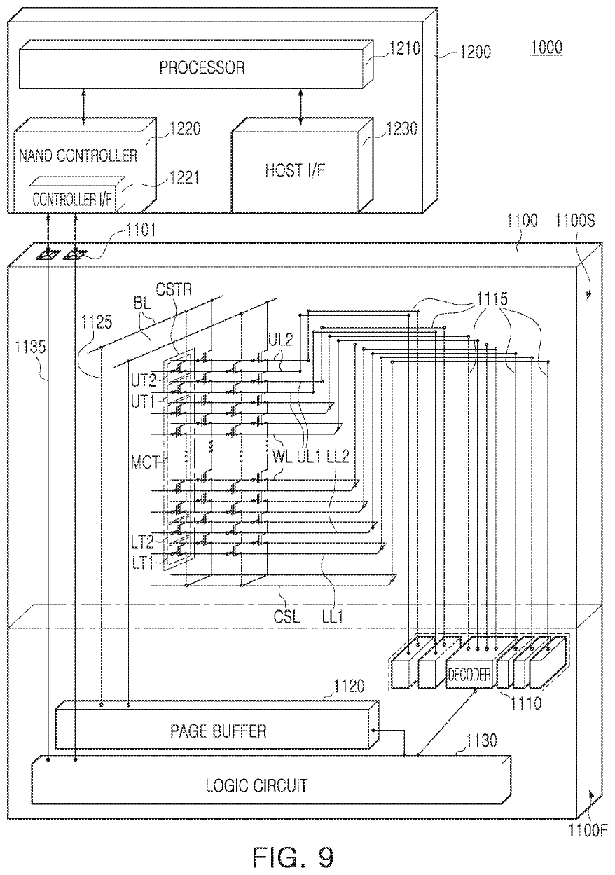

FIG. 9 is a view schematically illustrating an example of a data storage system including a semiconductor device.

Referring to FIG. 9, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD) including one or more semiconductor devices 1100, a universal serial bus (USB), a computing system, a medical device, or a communication device.

The semiconductor device 1100 may be a nonvolatile memory device, for example, a NAND flash memory device described above with reference to FIGS. 8A to 8C. The semiconductor device 1100 may include a first structure 1100F and a second structure 1100S on the first structure 1100F. In some example implementations, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a BL, a common source line (CSL), WLs, first and second gate upper lines UL1, UL2, first and second gate lower lines LL1, LL2, and memory cell strings (CSTRs) between the BL and the CSL.

In the second structure 1100S, each of CSTRs may include lower transistors LT1 and LT2 disposed adjacent to the CSL, upper transistors UT1 and UT2 disposed adjacent to the BL, and a plurality of memory cell transistors (MCTs) disposed between the lower transistors LT1 and LT2 and the upper transistors UT1 and UT2. The number of lower transistors LT1 and LT2 and the number of upper transistors UT1 and UT2 may be variously modified in some implementations.

In some example implementations, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The WLs may be gate electrodes of the MCTs, and the gate upper lines UL1 and UL2 may be gate electrodes of the upper transistors UT1 and UT2, respectively.

In some example implementations, the lower transistors LT1 and LT2 may include a lower erase control transistor LT1 and a ground selection transistor LT2 connected in series. The upper transistors UT1 and UT2 may include a string selection transistor UT1 and an upper erase control transistor UT2 connected in series. At least one of the lower erase control transistor LT1 and the upper erase control transistor UT2 may be used for an erase operation of deleting data stored in the MCTs using a GIDL phenomenon.

The CSL, the first and second gate lower lines LL1 and LL2, the WLs, and the first and second gate upper lines UL1 and UL2 may be electrically connected to the decoder circuit 1110 through first connection lines 1115 extending to the second structure 1100S within the first structure 1100F. The BLs may be electrically connected to the page buffer 1120 through second connection lines 1125 extending to the second structure 1100S within the first structure 1100F.

In the first structure 1100F, the decoder circuit 1110 and the page buffer 1120 may execute a control operation for at least one selected memory cell transistor among a plurality of MCTs. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending to the second structure 1100S within the first structure 1100F.

The controller 1200 may include a processor 1210, a NAND controller 1220, and a host interface 1230. In some implementations, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, control commands for controlling the semiconductor device 1100, data to be recorded in the MCTs of the semiconductor device 1100, and data to be read from the MCTs of the semiconductor device 1100 may be transmitted. The host interface 1230 may provide a communication function between the data storage system 1000 and an external host. When receiving a control command from an external host through the host interface 1230, the processor 1210 may control the semiconductor device 1100 in response to the control command.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

The present disclosure is not limited to the above-described implementations and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
a first semiconductor structure including a substrate, circuit elements on the substrate, and a capacitor structure on the circuit elements; and
a second semiconductor structure including a plate layer on the first semiconductor structure, gate electrodes stacked to be spaced apart from each other in a first direction, perpendicular to an upper surface of the plate layer and sequentially stacked on the plate layer, and channel structures penetrating through the gate electrodes and extending in the first direction,
wherein the capacitor structure comprises:
a first electrode structure including a first connection portion extending in a second direction, parallel to an upper surface of the substrate, and first finger portions extending from the first connection portion in a third direction, perpendicular to the second direction; and
a second electrode structure including a second connection portion extending in the second direction and second finger portions extending from the second connection portion in the third direction and alternately arranged with the first finger portions,
wherein the first electrode structure includes first lines and first contacts alternately stacked on each other in the first direction,
the second electrode structure includes second lines and second contacts alternately stacked on each other in the first direction, and
in the second finger portions, a lower surface of at least one of the second contacts is covered with an insulating layer so that the at least one of the second contacts is not connected to the second lines.

2. The semiconductor device of claim 1, wherein in the first finger portions, the first lines include first lower lines, first intermediate lines, and first upper lines, sequentially stacked on the substrate, and
in the second finger portions, the second lines are on levels different from a level of the first intermediate lines.

3. The semiconductor device of claim 2, wherein in the second finger portions, the second lines include only second lower lines on the same level as a level of the first lower lines and second upper lines on the same level as a level of the first upper lines.

4. The semiconductor device of claim 3, wherein in the first finger portions, the first contacts include first lower contacts connecting the first lower lines to the first intermediate lines, and first upper contacts connecting the first intermediate lines to the first upper lines, and
in the second finger portions, the second contacts include second lower contacts connected to the second lower lines and second upper contacts connected to the second upper lines.

5. The semiconductor device of claim 4, wherein in the second finger portions, the insulating layer is between upper surfaces of the second lower contacts and lower surfaces of the second upper contacts.

6. The semiconductor device of claim 2, wherein in the second connection portion, the second lines include second lower lines on the same level as a level of the first lower lines, second intermediate lines on the same level as a level of the first intermediate lines, and second upper lines on the same level as a level of the first upper lines.

7. The semiconductor device of claim 2, wherein the first and second lines except for the first intermediate lines are arranged at a first pitch in the second direction, and
the first and second contacts are arranged at the first pitch in the second direction.

8. The semiconductor device of claim 7, wherein the first pitch ranges from about 140 nm to about 240 nm.

9. The semiconductor device of claim 7, wherein the first intermediate lines are arranged at a second pitch greater than the first pitch.

10. The semiconductor device of claim 1, wherein each of the first contacts is on each of the first finger portions and each of the second contacts is on each of the second finger portions, and
the first and second contacts have a line shape extending in the third direction.

11. The semiconductor device of claim 1, wherein in the first finger portions, the first lines include first lower lines, first intermediate lines, and first upper lines, sequentially stacked on the substrate,
in the second finger portions, the second lines include second lower lines on the same level as a level of the first lower lines, second intermediate lines on the same level as a level of the first intermediate lines, and second upper lines on the same level as a level of the first upper lines, and
the first intermediate lines are only in some of the first finger portions, and the second intermediate lines are only in some of the second finger portions.

12. The semiconductor device of claim 1, wherein the capacitor structure further includes a dielectric layer between the first electrode structure and the second electrode structure.

13. The semiconductor device of claim 1, wherein the first electrode structure and the second electrode structure include a metal material.

14. The semiconductor device of claim 1, wherein the first semiconductor structure further includes an interconnection structure horizontally spaced apart from the capacitor structure on the circuit elements and including circuit interconnection lines and circuit contact plugs, and
at least some of the circuit interconnection lines are on the same level as a level of the first and second lines, and at least some of the circuit contact plugs are on the same level as a level of the first and second contacts.

15. A semiconductor device, comprising:
a first electrode structure on a substrate and including a first connection portion extending in a first direction, parallel to an upper surface of the substrate, and first finger portions extending from the first connection portion in a second direction, perpendicular to the first direction;
a second electrode structure on the substrate and including a second connection portion extending in the first direction, and second finger portions extending from the second connection portion in the second direction and alternately arranged with the first finger portions; and
an insulating layer between the first electrode structure and the second electrode structure,
wherein the first electrode structure includes first lines and first contacts alternately stacked on each other in a third direction, perpendicular to the upper surface of the substrate,
the second electrode structure includes second lines and second contacts alternately stacked on each other in the third direction, and
the first and second lines and the first and second contacts are arranged at a first pitch on N levels among a plurality of levels in the third direction, and are arranged at a second pitch greater than the first pitch on M levels of the plurality of levels, wherein Nis 3 or more, and M is less than N.

16. The semiconductor device of claim 15, wherein the second pitch is twice or more than the first pitch.

17. The semiconductor device of claim 15, wherein a lower surface of at least one of the second contacts is covered with the insulating layer so that the at least one of the second contacts is not connected to the second lines.

18. The semiconductor device of claim 15, wherein a lower surface of at least one of the second lines is covered with the insulating layer so that the at least one of the second lines is not connected to the second contacts.

19. A data storage system, comprising:
a semiconductor storage device including circuit elements on a substrate, memory cells, a capacitor structure, and an input/output pad; and
a controller electrically connected to the semiconductor storage device through the input/output pad and configured to control the semiconductor storage device,
wherein the capacitor structure comprises:
a first electrode structure including a first connection portion extending in a first direction, parallel to an upper surface of the substrate, and first finger portions extending from the first connection portion in a second direction, perpendicular to the first direction;
a second electrode structure including a second connection portion extending in the first direction, and second finger portions extending from the second connection portion in the second direction and alternately arranged with the first finger portions; and
an insulating layer between the first electrode structure and the second electrode structure,
wherein the first electrode structure includes first lines and first contacts alternately stacked on each other in a third direction, perpendicular to the upper surface of the substrate,
the second electrode structure includes second lines and second contacts alternately stacked on each other in the third direction, and
some of the second lines and the second contacts are vertically spaced apart from each other in the second finger portions.

20. The data storage system of claim 19, wherein the first and second lines and the first and second contacts are arranged at a first pitch on three levels of first to fourth levels in the third direction, and are arranged at a second pitch greater than the first pitch on one level of the first to fourth levels.
